(19) United States
(12) Patent Application Publication
(10) Pub. No.: US 2010/0059881 A1
(43) Pub. Date: Mar. 11, 2010

(54) SEMICONDUCTOR PACKAGE AND METHOD OF MANUFACTURING THE SAME

(75) Inventors: Woon-Chun Kim, Suwon-si (KR); Soon-Gyu Yim, Seongnam-si (KR); Joon-Seok Kang, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/388,217

(22) Filed: Feb. 18, 2009

(30) Foreign Application Priority Data
Sep. 5, 2008 (KR) 10-2008-0087908

(51) Int. Cl. H01L 23/498; H01L 21/768

(52) U.S. Cl. 257/737; 438/613; 257/E23.068; 257/E21.585

(57) ABSTRACT

A semiconductor package and a method of manufacturing the semiconductor package are disclosed. The semiconductor package in accordance with an embodiment of the present invention includes: a substrate, in which a conductive pattern formed on one surface of the substrate; an insulation layer, which is formed on one surface of the substrate, in which a through-hole is formed in the insulation layer such that the conductive pattern is exposed; a metal post, which is formed in the through-hole such that one end of the metal post is in contact with the conductive pattern and the other end of the metal post is protruded from the insulation layer; and a solder bump, which is formed on the other end of the metal post.

### CROSS-REFERENCE TO RELATED APPLICATIONS

This application claims the benefit of Korean Patent Application No. 10-2008-0087908, filed with the Korean Intellectual Property Office on Sep. 9, 2008, the disclosure of which is incorporated herein by reference in its entirety.

### BACKGROUND

1. Technical Field

The present invention relates to a semiconductor package and a method of manufacturing the semiconductor package.

2. Description of the Related Art

A semiconductor package, like a wafer level package (WLP) and a chip scale package (CSP), is manufactured by forming a insulation layer and a redistribution layer on a semiconductor substrate, on which electrodes are formed.

In addition, the semiconductor package allows a metal post to be formed on the redistribution layer and a solder to be formed on the metal post, in order to make an electrical connection with an external device, such as, for example, a main board.

In the conventional technology, however, the metal post is buried in the insulation layer, making it difficult to provide adequate adhesion between the metal post and a solder ball. This especially lowers the resistance against a lateral force.

### SUMMARY

The present invention provides a semiconductor package and a method of manufacturing the semiconductor package that improves adhesive force between a metal post and a solder bump.

An aspect of the present invention provides a semiconductor package. The semiconductor package in accordance with an embodiment of the present invention includes: a substrate, in which a conductive pattern formed on one surface of the substrate; an insulation layer, which is formed on one surface of the substrate and in which a through-hole is formed in the insulation layer such that the conductive pattern is exposed; a metal post, which is formed in the through-hole such that one end of the metal post is in contact with the conductive pattern and the other end of the metal post is protruded from the insulation layer; and a solder bump, which is formed on the other end of the metal post.

Here, the metal post can be formed such that the other end of the metal post bulges outward.

A diameter of the other end of the metal post can be greater than a diameter of the one end of the metal post.

In addition, the semiconductor package can further include a seed, which is interposed between the through-hole and the metal post.

Another aspect of the present invention provides a method of manufacturing a semiconductor package. The method of manufacturing a semiconductor package in accordance with an embodiment of the present invention includes: providing a substrate having a conductive pattern formed on one surface thereof; forming an insulation layer on one surface of the substrate, in which a through-hole is formed in the insulation layer such that the conductive pattern is exposed; forming a metal post in the through-hole such that one end of the metal post is in contact with the conductive pattern and the other end of the metal post is protruded from the insulation layer; and forming a solder bump on the other end of the metal post.

Here, the method can further include: between the forming of the insulation layer and the forming of the metal post, forming a resist on the insulation layer, in which the resist has a filling-hole formed therein such that the filling-hole corresponds with the through-hole; and between the forming of the metal post and the forming of the solder bump, removing the resist, in which the forming of the metal post is performed by filling a conductive substance in the through-hole and the filling-hole.

A diameter of the filling-hole can be greater than a diameter of the through-hole.

The method can further include, between the forming of the insulation layer and the forming of the resist, forming a seed in the through-hole, in which the forming of the metal post is performed through electroplating.

The forming of the seed can include: forming a seed layer on the through-hole and the insulation layer; and between the removing of the resist and the forming of the solder bump, removing the seed layer excluding an area of the seed layer formed on the through-hole.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross sectional view illustrating a semiconductor package in accordance with an embodiment of the present invention.

FIG. 2 is a flowchart illustrating a method of manufacturing a semiconductor package in accordance with another embodiment of the present invention.

FIGS. 3 to 12 are cross sectional views illustrating each process of manufacturing a semiconductor package in accordance with another embodiment of the present invention.

### DETAILED DESCRIPTION

Certain embodiments of the present invention will be described below in detail with reference to the accompanying drawings. For better understanding overall in describing aspects of the present invention, the same reference numerals are used for the same means, regardless of the figure number.

Also, if a component is described to be formed on another component, the forming not only refers to those cases where the components are in direct physical contact, but also encompasses those cases where a different element or elements are interposed between the components mentioned, with the components being in contact with the different element or elements respectively.

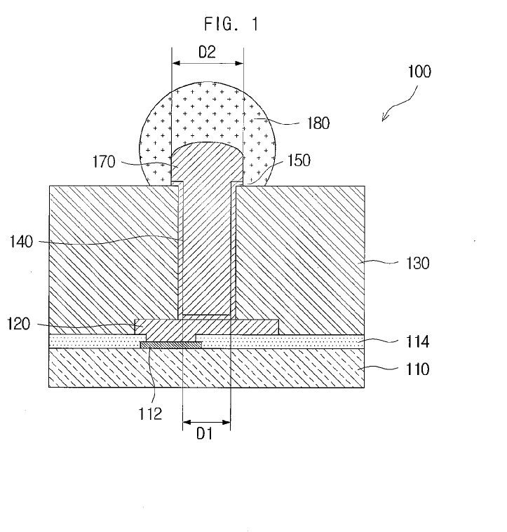

FIG. 1 is a cross sectional view illustrating a semiconductor package 100 in accordance with an embodiment of the present invention.

The semiconductor package 100 in accordance with the present embodiment includes a substrate 110, in which a conductive pattern 120 is formed on one surface of the substrate 110, an insulation layer 130, which is formed on one surface of the substrate 110 and in which a through-hole 140 is formed such that the conductive pattern 120 is exposed, a metal post 170, which is formed in the through-hole 140 such that one end of the metal post 170 is in contact with the conductive pattern 120 and the other end of the metal post 170 is protruded from the insulation layer 130, and a solder bump 180, which is formed on the other end of the metal post 170.

In accordance with the embodiment described above, by having the other end of the metal post 170 protrude from the insulation layer 130, adhesive force between the metal post 170 and the solder bump 180 can be improved because of the increased contact area. Therefore, after the semiconductor package 100 is coupled to an external device through the use of the solder bump 180, the resistance can be increased when a lateral load is applied widthwise to the semiconductor package 100.

Below, each component will be described in more detail with reference to FIG. 1.

The conductive pattern 120 is formed on one surface of the substrate 110. In this case, the substrate 110 can be a semiconductor substrate, for example, a silicon (Si) substrate. Described below is an example of the conductive pattern 120 being a redistribution layer that is formed on the substrate 110.

In other words, in the case of the present embodiment, an electrode 112 is formed on the substrate 110 made of silicon, and a protection layer 114 is formed on the substrate 110 such that the electrode 112 is exposed. Moreover, the conductive pattern 120, i.e., the redistribution layer, is formed on the protection layer 114 such that the conductive pattern 120 is electrically connected to the electrode 112.

Although the present embodiment discloses the conductive pattern being the redistribution layer, the conductive pattern can be an electrode being formed on the substrate 110. In this case, the protection layer and the redistribution layer described above can be omitted.

The insulation layer 130 is formed on one surface of the substrate 110, and the through-hole 140 is formed in the insulation layer 130 such that the conductive pattern 120 is exposed. That is, the insulation layer 130 is formed on the substrate 110 such that the conductive pattern 120 is covered, and the through-hole 140 is formed such that the through-hole 140 corresponds with the position of the conductive pattern 120 in order to form the metal post 170 being electrically connected with the conductive pattern 120.

In case the conductive pattern 120 is the redistribution layer, like the present embodiment, the through-hole 140 is formed such that a part of the conductive pattern 120 is only exposed. Likewise, if the conductive pattern is an electrode, unlike the present embodiment, the through-hole can be formed such that the through-hole corresponds with the size of the electrode.

One end of the metal post 170 is coupled to the conductive pattern 120 such that the metal post can be electrically connected with the conductive pattern 120.

By forming the metal post 170 as described above, the resistance of the semiconductor package 100 against a lateral load can be improved because the metal post 170 is microscopically deformed lengthwise little by little, dispersing the load, if the lateral load is applied widthwise to the semiconductor package 100 after the semiconductor package 100 is coupled to an external device, such as a main board.

The metal post 170 is formed inside the through-hole 140 such that the other end of the metal post is protruded from the insulation layer 130. That is, the other end of the metal post 170 being in contact with the solder bump 180 protrudes from a surface of the insulation layer 130. Therefore, an outer surface of the other end of the metal post 170 is in contact with the solder bump 180, significantly increasing the contact area between them.

As such, while the contact area created between the metal post 170 and the solder bump 180 increases, the adhesive force between them can be improved, and thus the resistance against the lateral force described above can be further improved.

In other words, by being in contact with the outer surface of the other end of the metal post 170 protruded from the insulation layer, a supporting force created by the metal post 170 and the solder bump 180 can further improve its resistance against external stimulation acting widthwise, because the supporting force against the lateral load exists not only lengthwise corresponding to the thickness of the semiconductor package 100 but also widthwise due to the outer surface of the other end of the metal post 170.

Furthermore, the metal post 170 is formed such that the other end of the metal post is bulging outward. By forming the other end of the metal post 170 to be bulging outward as described above, the supporting force of the horizontal direction elements described above can be further improved. Moreover, when the solder bump 180 is formed, solder paste can float easily along a surface of the other end of the metal post 170, allowing the solder bump 180 to be formed more easily as well as improving the bonding between the metal post 170 and the solder bump 180.

In addition, a diameter D2 of the other end of the metal post 170 is greater than a diameter D1 of the one end of the metal post 170. That is, the metal post 170 is shaped like a pole, in which the other end of the metal post 170 is thicker than the one end thereof, forming in a mushroomed shape.

Therefore, the contact area between the other end of the metal post 170 and the solder bump 180 increases, and the strength of the other end of the metal post 170 is improved, so that the supporting force or the resistance against the lateral force described above can be further improved.

The solder bump 180 is formed on the other end of the metal post 170. Since the other end of the metal post 170 is protruded from the insulation layer 130, if the solder bump 180 comes into contact with the other end of the metal post 170, the contact area between them can be increased as well as the supporting force against the lateral force, thereby implementing the semiconductor package 100 with enhanced stability and durability.

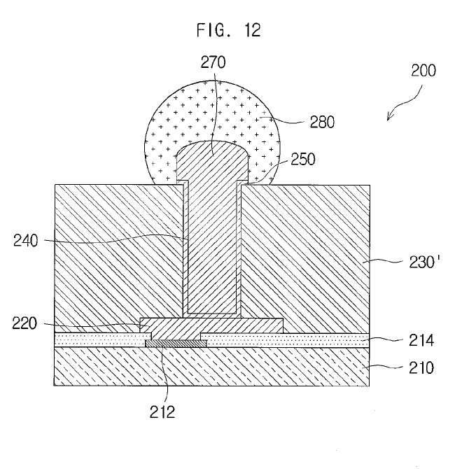

After coating the solder paste on the other end of the metal post 170, the solder bump 180 can be formed through a reflow process, and it can be also formed by directly coupling a solder ball. This will be described later when a semiconductor package 200 (in FIG. 12) in accordance with another embodiment of the present invention is described.

A seed 150 is interposed between the through-hole 140 and the metal post 170. The seed 150 can be formed inside the through-hole 140 for a following electroplating process. In other words, the seed 150 is formed inside the through-hole 140, and then the through-hole 140 is filled with a conductive substance through electroplating so that the metal post 170 can be formed.

By forming a resist with a filling-hole formed therein that corresponds with the through-hole 140 and then filling up the through-hole 140 and the filling-hole with the conductive substance, the metal post 170 can be formed such that the metal post is protruded from the insulation layer 130. That is, the resist can be used to form a mold that helps form the metal post 170.

Furthermore, since the electroplating proceeds along a surface of the seed 150, the other end of the metal post 170, which is formed inside the filling-hole of the resist without the seed 150 formed on the filling-hole, is formed in a convex shape. This will be described later when a semiconductor package 200 (in FIG. 12) in accordance with another embodiment of the present invention is described.

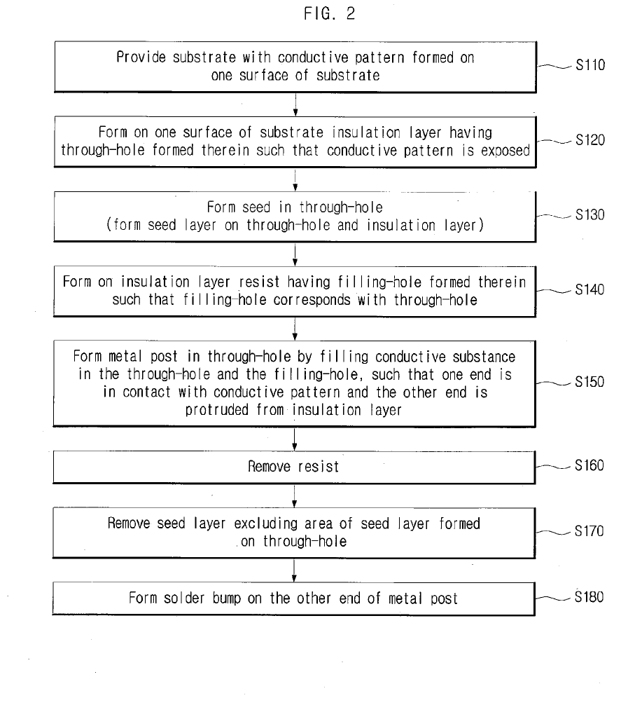

Next, a method of manufacturing a semiconductor package 200 in accordance with another embodiment of the present invention will be described by referring to FIGS. 2 to 12.

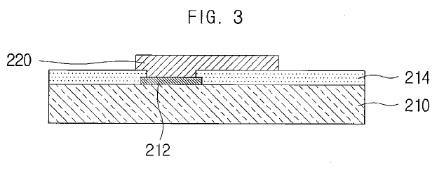

FIG. 2 is a flowchart illustrating the method of manufacturing the semiconductor package 200 in accordance with another embodiment of the present invention. FIGS. 3 to 12 are cross sectional views illustrating each process of the manufacturing method of the semiconductor package 200 in accordance with another embodiment of the present invention.

The method of manufacturing the semiconductor package 200 in accordance with the present invention includes providing a substrate 210 having a conductive pattern 220 formed on one surface thereof, forming an insulation layer 230′ on one surface of the substrate 210, in which a through-hole 240 is formed in the insulation layer 230′ such that the conductive pattern 220 is exposed, forming a metal post 270 in the through-hole 240 such that one end of the metal post 270 is in contact with the conductive pattern 220 and the other end of the metal post 270 is protruded from the insulation layer 230′, and forming a solder bump 280 on the other end of the metal post 270.

In accordance with the present embodiment, by forming the other end of the metal post 270 with the solder bump 280 formed thereon protruding from the insulation layer 230′, a contact area between the metal post 270 and the solder bump 280 can be increased, thereby improving the adhesive force between them. Therefore, after the semiconductor package 200 is coupled to an external device through the use of the solder bump 280, its resistance can be increased when a lateral load is applied widthwise to the semiconductor package 200.

Moreover, a grinding process, which is used to forming the conventional metal post, can be omitted, thereby simplifying the whole process and reducing the manufacturing time and costs.

Below, each process will be described in more detail with reference to FIGS. 2 to 12.

First, as illustrated in FIG. 3, the substrate 200 with the conductive pattern 220 formed on its one surface is provided (S110). In this case, the substrate 210 can be a semiconductor substrate, for example, a silicon (Si) substrate. Moreover, the conductive pattern 220 is a redistribution layer being formed on the substrate 210.

In other words, in the case of the present embodiment, an electrode 212 is formed on the substrate 210 made of silicon, and a protection layer 214 is formed on the substrate 210 such that the electrode 212 can be exposed. Moreover, the conductive pattern 220, i.e., the redistribution layer, is formed on the protection layer 214 such that the conductive pattern 220 is electrically connected to the electrode 212.

Disclosed in the present embodiment is an example of the conductive pattern being the redistribution layer. However, the conductive pattern can be an electrode being formed on the substrate 210, and, in this case, the protection layer and the redistribution layer described above can be omitted.

The protection layer 214 can be formed by way of, for example, photo-lithography, and the redistribution layer can be formed through, for example, an additive method or a subtractive method.

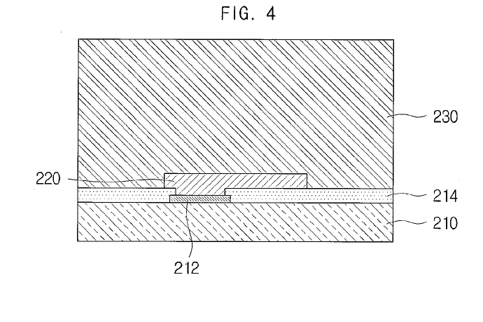

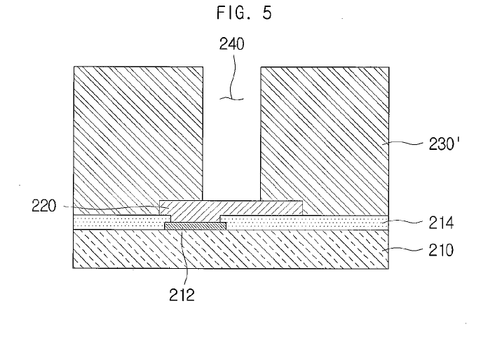

Then, as illustrated in FIGS. 4 and 5, the insulation layer 230′, in which the through-hole 240 is formed is formed on one surface of the substrate 210 such that the conductive pattern 220 is exposed (S120). This will be further described below.

First, as illustrated in FIG. 4, the insulation layer 230′ is formed such that the conductive pattern 220 is covered. After that, as illustrated in FIG. 5, the through-hole 240 is penetrated into the insulation layer 230′ to expose a part of the conductive pattern 220. Here, the through-hole 240 can be formed by way of photolithography or through the use of a laser drill such that the through-hole 240 can correspond with the location of the conductive pattern 220.

In case the conductive pattern is an electrode, the through-hole 240 can be formed to correspond with the size of the electrode, unlike the present embodiment.

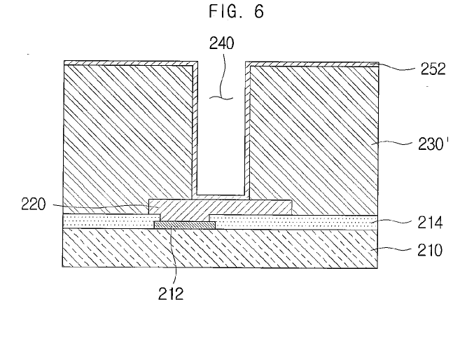

Then, as illustrated in FIG. 6, a seed 250 is formed inside the through-hole 240 (S130). This process is for forming the metal post 270 by way of electroplating.

In other words, by forming a seed layer 252 on the through-hole 240 and the insulation layer 230′ together at one time, the seed 250 can be formed inside the through-hole 240. Then, after the above process, by removing a part of the seed layer 252 by way of flash etching, only the seed 250 inside the through-hole 240 remains.

By forming the metal post 270 by way of electroplating through the use of the seed 250 or the seed layer 252, the metal post 270 can be formed more easily while improving the strength of attachment with the insulation layer 230′.

By forming the seed layer 252 on the through-hole 240 and the insulation layer 230′ together at one time in order to form the seed 250, the process can be simplified, and thus the efficiency can be improved because the forming of a resist for selectively removing parts of the seed layer 252 is not further needed to form the seed 250 in certain areas.

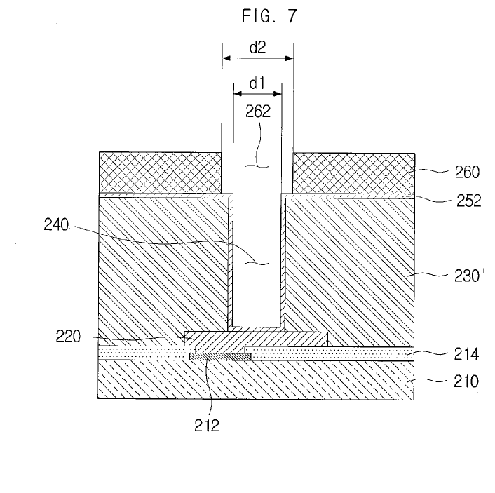

Next, as illustrated in FIG. 7, a resist 260 with a filling-hole 262 formed therein to correspond with the through-hole 240 is formed on the insulation layer 230′ (S140). In other words, the resist 260 having the filling-hole 262 formed therein is formed on an area of the seed layer 252 excluding the area formed in the through-hole 240 that corresponds with the position of the filling-hole 262. Here, the filling-hole 252 can be formed by way of photolithography or through the use of a laser drill.

In accordance with the way the resist 262 is formed as described above, the inner surfaces of the through-hole 240 is electroplated, and a conductive substance can be poured into the through-hole 240 and the filling-hole 262, forming the other end of the metal post 270 protruding from the electric layer 230′.

By forming the resist 260 as described above, only the through-hole 240 and the filling-hole 262 can be filled with the conductive substance, and the seed layer 252 formed on the insulation layer 230′ other than that formed on the through-hole 240 can be easily removed by way of flash etching in a following process.

A diameter D2 of the filling-hole 262 is formed to be greater than a diameter D1 of the through-hole 240. Accordingly, when the filling-hole 262 and the through-hole 240 are filled through electroplating in a following process, the efficiency of the manufacturing process of the metal post 270 can be further improved because a plating solution can be easily moved into the through-hole 240.

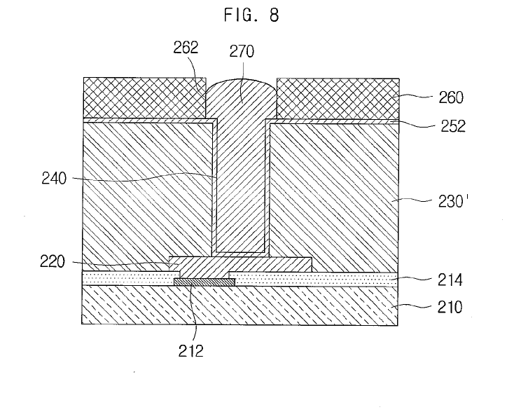

Then, as illustrated in FIG. 8, by filling the through-hole 240 and the filling-hole 262 with a conductive substance, the metal post 270 is formed in the through-hole 240 such that one end of the metal post 270 is in contact with the conductive pattern 220 and the other end is protruded from the insulation layer 230′.

In other words, through electroplating, by filling a conductive substance into the through-hole 240 on which the seed layer 252 is formed and the filling-hole 262 formed in the resist 260, the metal post 270, in which one end of the metal post is in contact with the conductive pattern 220, can be formed.

Like the semiconductor package 100 in FIG. 1 in accordance with an embodiment described above, by forming the metal post 270 as described above, the resistance of the semiconductor package 200 against a lateral load can be improved, after the semiconductor package 200 is coupled to an external device, such as a main board.

In addition, the metal post 270 is formed such that the other end of the metal post is protruded from the insulation layer 230′. That is, since the resist 260 is used as a mold that forms the other end of the metal post 270, plated layers forming from the seed layer 252 through electroplating can be filled inside the filling-hole 262 until the plated layers are blocked by the resist 260.

Like the embodiment of the semiconductor 100 (in FIG. 1) described above, by forming the other end of the metal post 270 being protruded from the insulation layer 230′, the resistance of the semiconductor package 200 against a lateral load can be further improved because the solder bump 280 can be in contact with an outer surface of the other end of the metal post 270, significantly increasing the contact area between them.

Since the electroplating proceeds along the surface of the seed layer 252, the filling-hole 262 of the resist 260 without the seed layer 252 formed inside the filling-hole is not filled with a conductive substance at the beginning of the electroplating process. However, after the inside of the through-hole 240 has been filled up while the electroplating process is proceeding, the other end of the metal post 270 is formed in a convex shape inside the filling-hole 262 as the conductive substance has filled up inside the filling-hole 262. In other words, since the inside of the filling-hole 262 is filled away from the through-hole 240 little by little, the other end of the metal post 270 can be formed such that the other end of the metal post 270 is bulging outward.

Like the semiconductor package 100 in FIG. 1 in accordance with an embodiment described above, by forming the other end of the metal post 270 to be convex as described above, a supporting force widthwise can be further improved. In addition, since the fluidity of the solder bump 282 is improved, the solder bump 280 can be formed more easily, and, at the same time, the tightness of contact between the metal post 270 and the solder bump 280 can be improved.

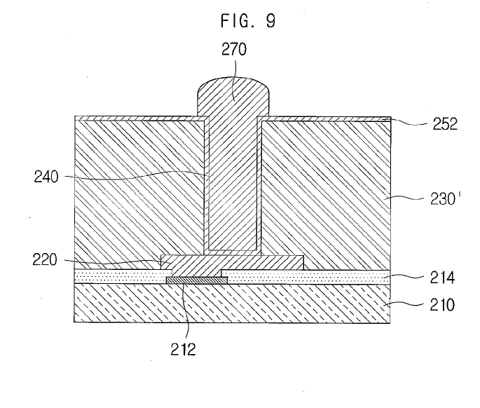

Then, as illustrated in FIG. 9, the resist 260 is removed (S160). After forming the metal post 270 by way of electroplating as described above, the resist 260 is removed.

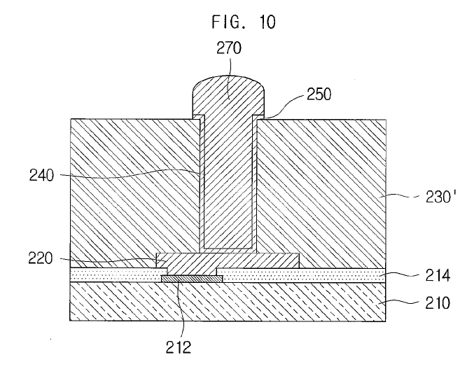

Next, as illustrated in FIG. 10, the seed layer 252 excluding the area formed inside the through-hole 240 is removed (S170). As described above, since the seed layer 252 is formed on the through-hole 240 and the insulation layer 230′, after the metal post 270 is formed, the seed layer, excluding the area forming the metal post 270, exposed to the outside is removed by way of flash etching. Therefore, the seed layer 252 only remains as the seed 250 inside the through-hole 240.

In addition, a part of the other end of the metal post 270 is also removed by way of flash etching.

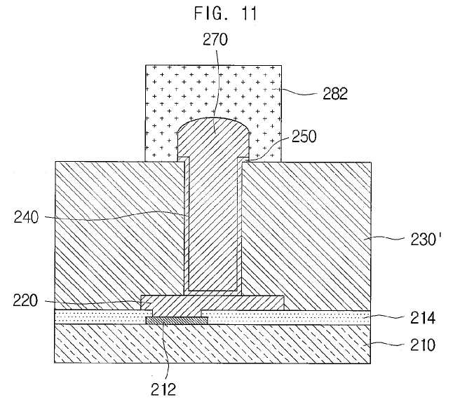

Next, as illustrated in FIGS. 11 and 12, the solder bump 280 is formed on the metal post 270 (S180). This will be further described below.

First, as illustrated in FIG. 11, a solder paste is coated on the other end of the metal post 270. The solder paste can be coated through, for example, a screen printing process.

Then, as illustrated in FIG. 12, the solder bump 280 in contact with the metal post 270 is formed by reflow soldering the coated solder paste 270. As a result, an outer surface of the other end of the metal post 270 can be coupled to the solder bump 280, thereby increasing the contact area and the adhesive force between them.

The solder bump 280 can be also formed by coupling a solder ball to flux, after coating the flux on the other end of the metal post 270, unlike the present embodiment, and it shall be apparent that this method is also included in the scope of the claims of the present invention.

According to the present embodiment as described above, before forming the solder bump 280, a process in which a grinding is used to smooth the other end of the metal post 270 can be omitted, thereby simplifying the overall process. Thus, the costs and time to manufacture can be reduced.

According to the embodiments of the present invention as set forth above, the contact area between the metal post and solder bump can be increased, improving the adhesive force between them. Therefore, after the semiconductor package is coupled to an external device through the use of the solder bump, its resistance can be increased when a lateral load is applied widthwise to the semiconductor package.

While the spirit of the invention has been described in detail with reference to certain embodiments, the embodiments are for illustrative purposes only and shall not limit the invention. It is to be appreciated that those skilled in the art can change or modify the embodiments without departing from the scope and spirit of the invention. As such, many embodiments other than those set forth above can be found in the appended claims.

What is claimed is:

1. A semiconductor package comprising:
a substrate, a conductive pattern formed on one surface of the substrate;
an insulation layer being formed on one surface of the substrate, a through-hole being formed in the insulation layer such that the conductive pattern is exposed;
a metal post being formed in the through-hole such that one end of the metal post is in contact with the conductive pattern and the other end of the metal post is protruded from the insulation layer; and
a solder bump being formed on the other end of the metal post.

2. The semiconductor package of claim 1, wherein the metal post is formed such that the other end of the metal post bulges outward.

3. The semiconductor package of claim 1, wherein a diameter of the other end of the metal post is greater than a diameter of the one end of the metal post.

4. The semiconductor package of claim 1, further comprising a seed being interposed between the through-hole and the metal post.

5. A method of manufacturing a semiconductor package, the method comprising:
providing a substrate having a conductive pattern formed on one surface thereof;
forming an insulation layer on one surface of the substrate, a through-hole being formed in the insulation layer such that the conductive pattern is exposed;
forming a metal post in the through-hole such that one end of the metal post is in contact with the conductive pattern and the other end of the metal post is protruded from the insulation layer; and
forming a solder bump on the other end of the metal post.

6. The method of claim 5, further comprising:
between the forming of the insulation layer and the forming of the metal post, forming a resist on the insulation layer, the resist having a filling-hole formed therein such that the filling-hole corresponds with the through-hole; and
between the forming of the metal post and the forming of the solder bump, removing the resist,
wherein the forming of the metal post is performed by filling a conductive substance in the through-hole and the filling-hole.

7. The method of claim 6, wherein a diameter of the filling-hole is greater than a diameter of the through-hole.

8. The method of claim 6, further comprising, between the forming of the insulation layer and the forming of the resist, forming a seed in the through-hole,
wherein the forming of the metal post is performed through electroplating.

9. The method of claim 8, wherein the forming of the seed comprises:
forming a seed layer on the through-hole and the insulation layer; and
between the removing of the resist and the forming of the solder bump, removing the seed layer excluding an area of the seed layer formed on the through-hole.
